(19) United States
(12) Patent Application Publication
(10) Pub. No.: US 2026/0300219 A1
(43) Pub. Date: Oct. 1, 2026

(54) 3D PROCESSOR

(71) Applicant: Massachusetts Institute of Technology, Cambridge, MA (US)

(72) Inventor: William S. Song, Lexington, MA (US)

(73) Assignee: Massachusetts Institute of Technology, Cambridge, MA (US)

(21) Appl. No.: 19/479,866

(22) PCT Filed: Mar. 12, 2024
(86) PCT No.: PCT/US2024/019512

§ 371 Date: Oct. 29, 2025

Related U.S. Application Data
(60) Provisional application No. 63/501,722, filed on May 12, 2023.

(51) Int. Cl. G06F 15/80; G06F 15/78; H10B 80/00

(52) U.S. Cl. CPC G06F 15/8046; G06F 15/7821; H10B 80/00

(57) ABSTRACT

Described is a device having three-dimensional (3D) integration of a DRAM die and processor ASIC. Such an integrated device achieves much higher memory bandwidth and low memory access power consumption than prior art devices while still retaining the high capacity and low cost of DRAMs. The devices and techniques described herein can result in much higher computational throughput, higher power efficiency, and lower cost per throughput than conventional processors while still providing the high memory capacity necessary to be able to work on large problems.

### CROSS-REFERENCE TO RELATED APPLICATIONS

This application claims the benefit under 35 U.S.C. § 119 of U.S. Provisional Patent Application No. 63/501,722 filed on May 12, 2023, which is hereby incorporated by reference herein in its entirety.

### GOVERNMENT LICENSE RIGHTS

This invention utilized government support under grant 2R44AG048758 awarded by the National Institute on Aging (of the National Institutes of Health). The government has certain rights in the invention.

### BACKGROUND

Artificial intelligence (AI) is becoming ubiquitous as increasing performance is enabling new capabilities to improve peoples' lives. Current AI processing, including generative AI processing, requires high computational throughput and it is likely that next-generation AI systems will require even more processing, cost more, and consume much more power, contributing significantly to increasing levels of global warming.

### SUMMARY

FIG. 1 shows a simple example neural network 100, where the circles represent neurons. The neurons are arranged in multiple layers including an input layer 102, a hidden layer 104, and an output layer 106. The input layer 102 of neurons receives external input signals. These signals are then multiplied by unique weights and sent to the next layer of neurons (hidden layer 104 in FIG. 1), as illustrated with arrows between layers 102 and 104. The neurons in hidden layer 104 sum the received signals, multiply the sums with unique weights, and then send the product signals to the next layer of neurons, shown as the output layer 106 in the simple example of FIG. 1. The neurons of output layer 106 sum the input signals and output the results. In practice, there can be a very large number of neurons in each layer, and there can also be a large number of hidden layers.

The computations in neural networks can be modeled as matrix computations. The sums of the input signals into a neuron layer can be thought of as an input vector, and the products between input elements and unique weights can be thought of as partial products. The sums of the partial products in the next neuron layer can be thought of as an output vector. The multiplication by weights and summing operations can be thought of as a matrix-vector multiplication operation. Therefore, processors designed for neural network implementations are generally optimized for matrix computations.

In recent years, efforts have been made to speed up processing for neural network implementations for AI applications. Many different architectures were typically used, including central processing units (CPUs), graphics processing units (GPUs), tensor processing units (TPUs), and other specialized architectures. AI processing tends to require high memory bandwidth because it generally does relatively few processing tasks per memory access. For each neural network weight value accessed from memory, only one weight multiplication is performed, whereas other types of scientific and numerical processing perform many arithmetic computations for each memory access. Some TPUs and GPUs process large batches of data in parallel and perform many multiplications and accumulates per weight accessed from memory, thus requiring fewer memory accesses per each computation performed.

Unlike some large data center AI applications, other AI applications such as embedded and edge computing applications generally do not process large batches of data in parallel, and thus need high memory bandwidth and also low memory power consumption per memory access. Many low latency applications such as self-driving vehicles and military applications can also require high memory bandwidth and low power consumption.

AI processors typically use some sort of dynamic memory (DRAM), since they provide high memory capacity at reasonable costs. Many different forms of DRAMs are used, including synchronous DRAM (SDRAM), graphics double data rate DRAM (GDDR DRAM), and high bandwidth memory (HBM). Although these DRAMs provide high memory capacity at reasonable costs, they are limited in memory bandwidth because they reside in a separate package from the processor and the communication path to the memory often becomes the principal performance bottleneck. The communication path also significantly increases the system power consumption because it consumes much more power per bit transmitted/received than the memory bit operations.

Some AI processors try to eliminate the memory access bottleneck by using static random-access memory (SRAM) built into the processor application-specific integrated circuit (ASIC) die. Normally, processors use SRAMs on the same die mostly for cache memory, and the main memory is DRAM that is on a separate die/package. However, some AI processors use SRAMs as main memory on the same die to achieve high memory bandwidth. In order to get the necessary higher memory capacity, a very large die may be required (e.g., a dinner plate-sized die). Although a larger processor die with high-capacity SRAMs on board can eliminate the memory bottleneck, it comes at a significant cost because larger dies cost significantly more to fabricate than a small die. Even with such large dies, it is difficult to match the capacity of DRAMs, so it is difficult for on-chip-SRAM-based AI processors to have high capacity main memory. This limits these processors' work on large-scale AI problems and increases the processor cost.

Another attempt to alleviate the memory bottleneck is using the processing in memory (PiM) concept. SAMSUNG developed DRAM dies that use DRAM fabrication process devices within the DRAM die to implement logic devices to perform matrix multiplications and other arithmetic functions. However, because the logic devices implemented in DRAM fabrication process are much larger, slower, and power hungry than the logic devices in ASIC fabrication processes, the performance gain, although significant, was limited. In addition, up to half the die area in the DRAM die had to be dedicated to the logic devices, thus reducing the DRAM capacity.

This disclosure describes three-dimensional (3D) integration of a memory die (e.g., DRAM die) and processor ASIC that may be used to achieve significantly higher memory bandwidth and low memory access power consumption compared to the state of the art, while still retaining the high capacity and low cost of DRAMs, for example. This can result in higher computational throughput, higher power efficiency, and lower cost per throughput than conventional processors (e.g., conventional AI processors) while still providing the high memory capacity necessary to be able to work on large problems. Other types of memories may be used with the disclosed concepts and structures. For example, non-volatile memories such as FLASH memory may be used. It is appreciated herein that such memories may have higher capacity compared to DRAM, but lower read/write speeds and lower endurance with limited read/write cycles.

According to one aspect of the disclosure, a processor die is situated or disposed on top of a memory die and with the two dies connected using 3D signal paths (e.g., signal paths that extend vertically between the dies, in addition to those found within the horizontal plane of the dies). In some embodiments, the memory die may comprise multiple memory banks with a processor core disposed above each (on the separate processor die), with the processor cores and memory banks having similar or identical shape and/or size (e.g., surface area). The memory and processor data flows through 3D signal paths between two dies. The general concepts described herein may be used to provide a 3D processor suitable for use in various applications, including AI applications.

With existing processors, input and output signals from multiple memory banks go through a common interface, such as double data rate (DDR) interfaces in case of SDRAMs. It is appreciated herein that the common interface may be eliminated by providing simple individual low-power interfaces for each memory bank or utilizing such interfaces provided by existing memory banks. Individual interfaces can be simpler than a common interface in that they do not have to coordinate inputs and outputs associated with many memory banks.

While the general 3D processor concept described herein is well suited for neural network processing, it is possible to extend the concept for other applications. For example, processor cores that directly interface with individual memory banks can be optimized for different types of applications. The general concepts and structures disclosed herein can provide high memory bandwidth, low memory access power per bit access, high memory capacity, and low memory cost for various applications for which such merits are important. In some cases, processor cores for such applications can be designed to read or write to the memory one complete word at a time, further improving efficiency.

Potential applications of the disclosed technique include, but are not limited to: AI inference, AI training, various levels of self-driving, high-bandwidth memory systems, matrix processing, sparse matrix processing, graph processing, real-time trading/finance, data security, database processing, database search, finite element methods, digital signal processing, image processing, video processing, sensor array processing, communications, sorting, medical imaging, entertainment, gaming, graphics processing, personal computing, parallel computing, super computing, CAD/CAM, mobile computing, and Internet of Things (IoT).

For at least some of these applications, the performance improvement, power savings, and cost savings are projected to be very significant. For example, compared to LPDDR4 (Low-Power Double Data Rate) SDRAM dies, the proposed die stack may provide up to 100× memory bandwidth and 100× power efficiency with associated cost savings.

Disclosed 3D processors can be used to provide providing edge AI computing (e.g., in mobile and automotive applications) with low power consumption. Although high memory bandwidth provides the low latency needed, the duty cycle can be kept low because computing data input, such as voice input or visual input, will likely be provided sporadically (a few words per second or less, tens of frames per second or less) for critical applications such as natural language user interface and various levels of self-driving. Disclosed 3D processors may consume as little as a few milliwatts of power.

According to one aspect of the disclosure, a 3D processor includes: a memory die having a plurality of memory banks; a processor die disposed over the memory die and having a plurality of processor cores connected as a systolic array; and a plurality of signal paths configured to couple the memory die to the processor die, wherein each of the processor cores is disposed over at least one of the plurality of memory banks and connected thereto by at least one of the plurality of signal paths.

In some embodiments, the memory banks are disposed on a horizontal surface of the memory die, the processor cores are disposed on a horizontal surface of the processor die, and the signal paths extend vertically between the memory die and the processor die. In some embodiments, each of the processor cores have a first area on the horizontal surface of the memory die, each of the memory banks have a second area on the horizontal surface of the memory die, and the first and second areas are substantially equal.

In some embodiments, the plurality of processor cores comprises a plurality of application-specific integrated circuits (ASICs). In some embodiments, each of the plurality of ASICs is configured to perform the same arithmetic operations. In some embodiments, at least two different ones of the plurality of ASICs are configured to perform at least two different arithmetic operations.

In some embodiments, the plurality of processor cores are configured to read and write data to the plurality of memory banks using individual memory interfaces. In some embodiments, the plurality of processor cores are connected as a one-dimensional (1D) systolic array. In some embodiments, the plurality of processor cores are connected as a two-dimensional (2D) systolic array.

According to another aspect of the disclosure, a processing network can include a plurality of processing nodes connected as a systolic array, where each node corresponds to a 3D process as described above. The nodes can be connected as a 1D or 2D systolic array, for example.

According to another aspect of the disclosure, a system includes: a control & I/O processor; and a processor die having a plurality of processor nodes connected as a systolic array and each connected to the control & I/O processor via one or more buses, wherein each of the plurality of processor nodes has a routing module a processor core connected to a memory bank via an individual memory interface.

In some embodiments, the routing modules are configured to send and/or receive data from the control & I/O processor via at least one of the one or more buses. In some embodiments, the one or more buses include a broadcast bus connecting the control & I/O processor to each of the processor nodes.

In some embodiments, the memory banks are configured to store neural network weights, the control & I/O processor is configured to broadcast input vector elements to the plurality of processor nodes via the broadcast bus, and the plurality of processor nodes are configured to read the neural network weights from the memory banks and to multiply the input vector elements by the neural network weights to produce output vector elements. In some embodiments, the processor nodes are configured to shift out the output vector elements to the control & I/O processor via the systolic array. In some embodiments, the one or more buses include a control bus configured to program the neural network weights stored on the memory banks. In some embodiments, the processor die is a first processor die, wherein the system further comprises: a second processor die having a plurality of processor nodes connected as a systolic array and each connected, wherein the control bus is arranged to connect the first and second processor dies.

It should be appreciated that individual elements of different embodiments described herein may be combined to form other embodiments not specifically set forth above. Various elements, which are described in the context of a single embodiment, may also be provided separately or in any suitable sub-combination. It should also be appreciated that other embodiments not specifically described herein are also within the scope of the following claims.

### BRIEF DESCRIPTION OF THE DRAWINGS

The manner of making and using the disclosed subject matter may be appreciated by reference to the detailed description in connection with the drawings, in which like reference numerals identify like elements.

FIG. 1 is a schematic diagram showing a simplified neural network.

FIG. 2 is a perspective view of a 3D processor, according to some embodiments.

FIG. 3 is a cross-sectional view illustrating a die integration that may be used with a 3D processor, according to some embodiments.

FIG. 4A is schematic diagram illustrating a one-dimensional (1D) systolic array architecture, according to some embodiments.

FIG. 4B is schematic diagram illustrating a two-dimensional (2D) systolic array architecture, according to some embodiments.

FIG. 5 is a block diagram showing an implementation of a 3D processor die having a 1D semi-systolic array architecture, according to some embodiments.

FIG. 6 is a block diagram illustrating a systolic processing core (SPC) architecture, according to some embodiments.

FIG. 7A is a schematic diagram illustrating a 1D toroidal array architecture, according to some embodiments.

FIG. 7B is a schematic diagram illustrating a 2D toroidal array architecture, according to some embodiments.

The drawings are not necessarily to scale, or inclusive of all elements of a system, emphasis instead generally being placed upon illustrating the concepts, structures, and techniques sought to be protected herein.

### DETAILED DESCRIPTION

FIG. 2 shows a 3D-integrated processor 200, according to some embodiments. A processor die 202 having a plurality of processor cores 206a, 206b, etc. (206 generally) can be situated or disposed on top of a memory die 204 having a plurality of memory banks 208a, 208b, etc. (208 generally). Processor 200 comprising both memory die 204 and processor die 202 may be said to have a “3D die stack” or “3D die” for short.

Processor cores 206 and memory banks 208 may be connected using 3D signal paths, meaning signal paths that run not just alone the plane of the die (e.g., the x-y plane in FIG. 2), but also along the perpendicular axis (e.g., the z axis in FIG. 2).

In the example shown, each of the processor cores 206a, 206b, etc. may be disposed over a corresponding one of the memory banks 208a, 208b, etc. Also in the example of FIG. 2, the processor cores 206 and memory banks 208 can be arranged as 2D arrays on the respective dies 202 and 204. While FIG. 2 shows twelve (12) processor cores and twelve (12) corresponding memory banks, arranged in a 4×3 array, the generally concepts and structures described herein can provide for 3D processors having other numbers of processor cores and memory banks. As one example, a 3D processor may have 1024 processor cores and 1024 memory banks.

In some embodiments, each of the processor cores 206 may have similar, if not identical, surface areas (e.g., dimensions in the x-y plane) to each of the memory banks 208. For example, as shown in FIG. 2, processor core 206a can have the same width and length as memory bank 208a, processor core 206b can have the same width and length as memory bank 208b, etc. (where width and length are measured along the x and y axes, respectively, in the figure). In some cases, the area of the process cores can be substantially equal to that of the memory banks. For example, the areas can be within ±1%, ±5%, ±10%, or ±20% of each other. This allows each processor core to be perfectly, or nearly perfectly aligned, with each corresponding memory bank in the x-y plane and allows them to be compactly stacked on top of each other. This can be done to increase (and ideally maximize) density on the dies, allowing for a greater number of 3D processor cores on a given die surface; to reduce (and ideally minimize) the total surface area of the dies for a given number of 3D processor cores; and/or to improve (ideally maximize) performance.

A given memory bank 208 may be configured to store many bits of data in a memory cells. Data can be read and written to a memory bank 208 in “words,” each word corresponding to many bits (e.g., thousands of bits). That is, all the bits belonging to a word can be tied together by a “word line” and all the bits tied to a word line are read or written together. In more detail, a word line in a DRAM bank may consist of a few thousand bits (e.g., 4K or 8K bits), may be read out through a DRAM interface in smaller portions (e.g., 64 bits at a time). In some embodiments, memory banks 208 may be provided as DRAMs. In some embodiments, memory banks 208 may be provided as non-volatile memories such as FLASH memory. In other embodiments, memory banks 208 may be provided as non-volatile memory components. Individual memory banks 208 may have their own input/output (I/O) interfaces such that different memory banks 208 can concurrently perform different read/write operations. Processor cores 206 interface directly with memory banks 208 using these individual I/O interfaces. For example, to access a 64-bit portion of a word line from a memory bank, a processor core can specify (over the 3D signal paths) address bits of a particular word line and of a particular portion thereof (e.g., a beginning and an end of a 64-bit portion thereof). To access multiple portions of a particular word line, or of different word lines, the memory bank can send read data 64-bits at a time to the processor core.

Processor cores 206 can be configured to read or write one complete word at a time to take full advantage of the available memory bandwidth. Memory banks 208 may be organized so that a full word is read or written during each memory access cycle. Fortunately, for matrix-based AI computations, it is relatively straightforward to organize memory access in this way, as a word can represent entire row or column (or partial row or column) of the neural network weight matrix.

A processor core 206 can include circuitry (e.g., an ASIC) configured to execute a set of instructions, such as arithmetic instructions, memory operations, and control operations. The particular circuitry and instruction set provided by a processor core 206 can be selected based on the type of application the 3D processor 200 is intended to be used with. In some embodiments, all processor cores 206 on the die 202 may be identically configured. In other embodiments, different processor cores 206 on the die 202 may be differently configured. For example, different processor cores 206 may be provided as different types of ASICs to complete different sub-tasks of a larger AI problem/application. Additional details of processor cores 206 including how they can be interconnected and controlled are provided below and in subsequent figures.

The 3D signal paths between the two dies 202, 204 allow data to flow directly between memory banks 208 and processor cores 206 situated there above. This arrangement eliminates the common interface bottleneck found in conventional DRAM. For example, with processor 200, a word of data (which may include thousands of bits) can be read from a memory bank 208 and output through one or more 3D signal paths to a processor core 206 directly above it. Conversely, a word from a processor core 206 can be written into a memory bank 208 below it.

The memory configuration illustrated in FIG. 2 has many advantages over conventional memory (e.g., conventional DRAM modules). Since there are individual I/O interfaces to each memory bank rather than one common interface for all the memory banks, the memory bandwidth is much larger than conventional memory. All the memory banks can be accessed in parallel by all the cores rather than accessing one bank at a time as in conventional memory. In addition, since the vertical signal paths between the memory banks and processor cores can be made relatively short, associated parasitic capacitances are minimal. This greatly reduces the power consumption associated with memory access in terms of power spent per bit accessed (written or read). In addition, the disclosed memory configuration retains the high memory capacity and low cost per bit features of existing memory (e.g., DRAM).

The 3D processor illustrated in FIG. 2 is merely one example of the general concept sought to be protected herein. Other variations to this concept are possible as well. For example, for applications that require lower memory bandwidth, a 3D memory interface may be shared between a single processor core and multiple memory banks. As another example, a 3D memory interface may be shared between multiple processor cores and a single memory bank. The general concepts described herein can be extended to provide 3D dies having three or more layers. For example, a three-layer stack may include a processor die, a DRAM die, and a non-volatile memory die. The non-volatile memory can be used as a high bandwidth on-package disk drive for the die stack, for example. As another example, a die stack may include a processor die and two or more DRAM dies.

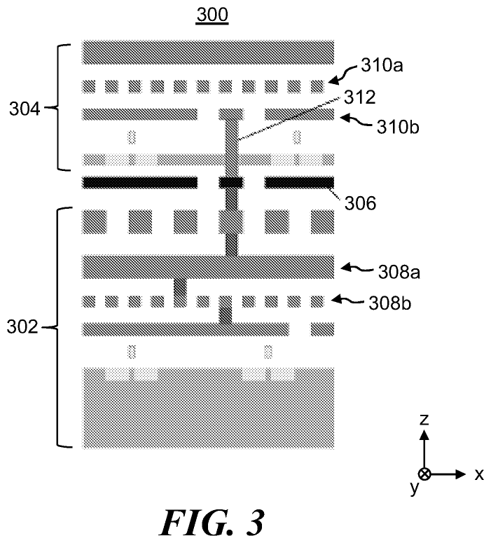

FIG. 3 shows an example of 3D die integration. In this example, multiple layers of metal interconnect layers, and insulator layers are used to make electrical connections between device layers.

As shown, a structure 300 can include a first device layer 302 and a second device layer 304 disposed thereover. The two device layers 302, 304 may be attached by a layer-to-layer bond 306. Each device layer may include signal paths formed along a 2D plane. For example, first device layer 302 can include a series of signal paths 308a (e.g., wires or other electrically conductive paths) oriented in the x-axis direction and another series of signal paths 308a oriented in the y-axis direction. Similarly, second device layer 304 can include a series of signal paths 310a oriented in the y-axis direction and another series of signal paths 310b oriented in the x-axis direction.

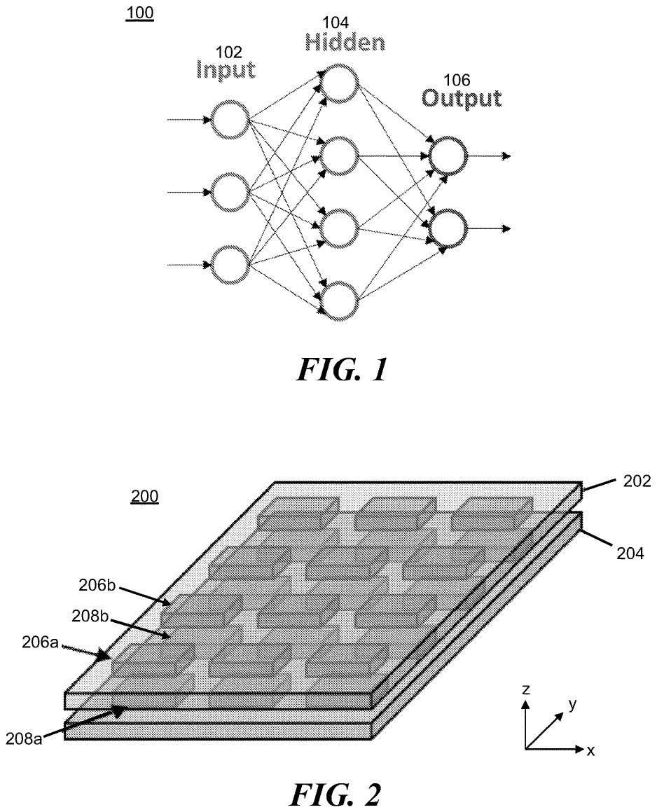

The different device layers 302, 304 may correspond to different wafer dies such as DRAM and ASIC dies. For example, device layers 302 and 304 may correspond to dies 204 and 202, respectively, of FIG. 1. As shown in the figure, bottom device layer 302 may be thicker than top device layer 304 to provide mechanical integrity.

The two device layers 302, 304 may be connected via one or more layer interconnects 312. In more detail, 2D signal paths of device layer 302 may be connected to 2D signal paths of device layer 304 via perpendicular layer interconnects 312 such that the overall structure 300 can be said to have 3D signal paths. The layer interconnects 312 can have a length of a few routing layer thicknesses on the dies compared to the die dimension which is many orders of magnitude larger. Using very short vertical signal paths between the memory banks and processor cores means that the parasitic capacitances associated with the signal paths are minimized.

Various commercially available 3D die stacking processes can be used to form structures that are the same as or similar to that shown in FIG. 3.

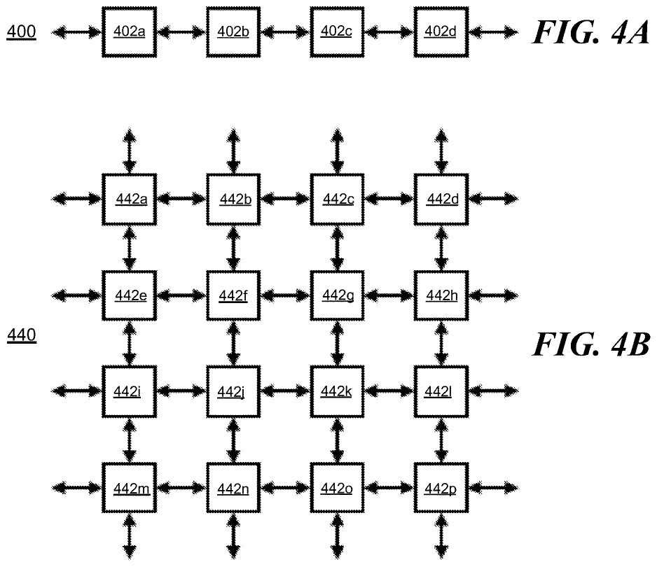

Turning to FIGS. 4A and 4B, to handle large computations (e.g., large neural network computations), multiple processor cores may be used. Thus, as illustrated in FIG. 2, a single 3D die can have multiple interconnected processor cores. To further increase processing capacity, multiple 3D dies each having multiple processor cores may be interconnected. In such cases, it is critical that the processor cores within a die and across multiple dies be connected in such a way as to enable efficient implementation of such coordinated computations.

FIG. 4A shows an example if a ID systolic array architecture 400 having processing nodes 402a, 402b, 402c, 402d, etc. (402 generally). FIG. 4B shows an example of a 2D systolic array architecture 440 having processing nodes 442a, 442b, . . . , 442p, etc. (442 generally). Both the 1D and 2D architectures can effectively implement large matrix multiplications across multiple processing nodes.

Systolic arrays generally consist of 1D or 2D arrays of replicated processing nodes that perform identical tasks. The signal communication paths generally include only nearest neighbor connections, keeping the paths short and efficient. For example, in 1D architecture 400, node 402b is connected to neighboring node 402a and 402c. As another example, in 2D architecture 440, node 442f is connected to neighboring nodes 442b, 442j, 442e, and 442j (which may be referred to as the north, south, east, and west neighbors).

Systolic arrays are efficient in implementing matrix operations, including neural network-weight multiplication operations. In addition, the communication bandwidth between the processor cores in matrix multiplication is much less than memory access bandwidth, and the communication paths can be implemented with relatively low-bandwidth links. The architectures also reduce the design effort because the processor cores are generally kept small, enabling a high degree of design optimization, and the entire computing structure is generated by replication. Therefore, such processor systems can be designed by relatively small teams.

The illustrated processing nodes 402, 442 may correspond to processing cores within a single 3D die, or to separate 3D dies within a processor network. In other words, a systolic array configuration can be used to interconnect multiple cores within a 3D die and/or to interconnect multiple 3D dies within a processor network. Designing a processor network in this case can be helpful in producing efficient implementations that can work well with different problem sizes. Moreover, because disclosed 3D dies can achieve low average power consumption, multiple 3D dies can be stacked on top of each other to achieve a small form factor.

It should be appreciated that a 2D array of 3D processor cores can be connected to form either a 1D or 2D systolic array. For example, the 3×4 array illustrated in FIG. 2 can be connected as a 2D systolic array where each 3D processor core is connected to up to four (4) of its nearest neighbors. As another example, the 3×4 array illustrated in FIG. 2 can be connected as a 1D systolic array where each 3D core is connected to one of its nearest neighbors, e.g., all cores within each row can be connected together serially, and the rows themselves can also be connected together serial, in a serpentine manner.

Next described are examples of systolic hardware implementations that can efficiently implement matrix-vector multiplications (e.g., for AI inference). With the described implementations, 1D semi-systolic array architecture is used within the 3D processor die, and either a 1D or 2D systolic array architecture can be used for connecting multiple 3D dies together. It will be understood from earlier discussions that a 3D die stack includes both a processor die and a memory die. As previously discussed, is possible that more than one layer of memory is included in a 3D die stack.

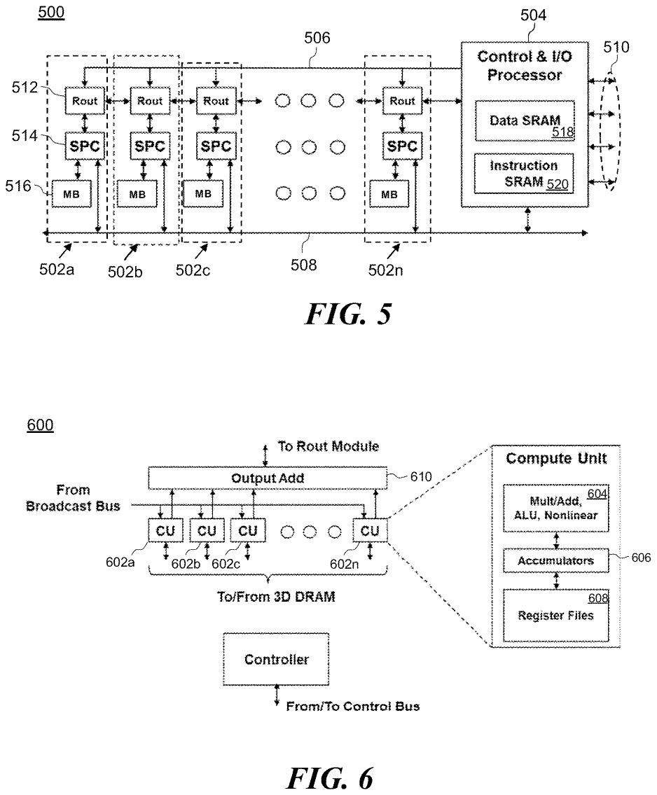

FIG. 5 shows an implementation of a 3D processor die 500 having a 1D semi-systolic array architecture, according to some embodiments. Processor die 500 includes a plurality of systolic processor nodes (SPNs) 502a, 502b, 502c, . . . , 502n (502 generally) each connected to a control & I/O processor 504 via a broadcast bus 506 and via a control bus 508, as shown.

Control & I/O processor 504 can include data SRAM 518 and instruction SRAM 520. SRAMs 518, 520 can be used by control & I/O processor 504 for cache memory, scratch pad, instruction cache, instruction memory, etc. In addition to SRAMs 518, 520, control & I/O processor 504 can include circuitry configured to send and/or receive data over buses 506, 508 and I/O ports 510. Moreover, control & I/O processor 504 can include circuitry configured to control all the processing, control, and timing of circuitry within the SPNs 502, including 512, 514, and 516.

Control & I/O processor 504 has four I/O ports 510 that can be connected to up to four other 3D processor for sending and receiving data. If 3D processor die 500 is used within a processor network having a 2D systolic array architecture, the four I/O ports 510 may be connected to nearest neighbors to the north, south, east, and west. If 3D processor die 500 is used within a processor network having a ID systolic array architecture, only two of the four I/O ports 510 may be used. Alternatively, the implementation of 3D processor die 500 may be modified to have only two I/O ports.

The SPNs 502 may be similar in structure and function. Representative SPN 502a includes a routing module 512 and a systolic processor core (SPC) 514. SPC 514 may be directly connected to a memory bank 516 via an individual low-power memory interface. Memory bank 516 can be provided on a separate die that is situated under 3D processor die 500, such as illustrated in FIG. 2. In other words, while the 3D processor die 500 of FIG. 5 is shown as having a plurality of memory banks, it should be understood that these memory banks may be disposed on a separate die situated under the 3D processor die.

3D processor die 500 may be used to perform matrix-vector multiplications associated with neural networks, for example. Control & I/O processor 504 can be configured to broadcast input vector elements to all the SPNs 502 simultaneously over the broadcast bus 506. Control & I/O processor 504 can receive such input vectors via one or more of the I/O ports 510 and store (e.g., on a temporary basis) input vectors in data SRAM 518. At each SPN 502, the routing module 512 can communicate the broadcasted input vector elements to the SPC 514. Due to such broadcasting, 3D processor die 500 can be said to have a “semi-systolic” array architecture. In some cases, control & I/O processor 504 can broadcast an input vector of size N one element at time over N successive clock cycles.

A top-level controller (not shown) can be connected to the systolic array that controls all the processing and handles the input/output that are going on in all the systolic array dies. Input vectors can be inputted to the 3D die stack through the ports 510 and stored in 518 before they are used or used as they come in. Output vectors can also be stored before they are outputted from the die stack or outputted as they are generated. I/O of the input and output vectors to/from the individual cores are handled through routing module 512 and is controlled by the control & I/O processor 504.

The SPC 514 can be configured to multiply the input vector elements by neural network weights read from the SPN's individual memory bank 516, and produce output vector elements. Each memory bank 516 may store a subset of weight matrix rows that belong to the output vector elements to be computed for the corresponding SPC 514. Various techniques may be employed to program/store weight matrix rows onto the various memory banks. For example, each core/bank can store subset of the weight matrix rows. This can done ahead of time by the control & I/O processor through the control bus 508. All the programming, control, timing, etc. can happen over the control bus.

The computed output vector elements can then be shifted out serially to control & I/O processor 504 through the routing module 512. In other words, over successively clock cycles, each SPN can send its output vector to its nearest neighbor (e.g., to its rightmost neighbor in FIG. 5), which in turn passes the output vector to its nearest neighbor, and so on until the output vector reaches control & I/O processor 504. While the operation of a single SPN is described, it should be appreciated that multiple SPNs 502 (or even all SPNs) can perform these steps in parallel.

When a single 3D die is used to implement a matrix-vector multiplication, each SPC 514 contributes to computation of specific output vector elements. Each memory bank 516 stores the corresponding weight matrix elements necessary for computation of the specific output vector elements.

While 3D processor die 500 can be used to perform matrix-vector multiplications associated with neural networks, the general concepts and structures described can be applied to various types of compute applications. In general, an SPC 514 can include circuitry (e.g., an ASIC) configured to execute a set of instructions, including but not limited to various types of arithmetic instructions. The particular circuitry and instruction set/AP provided by a SPC 514 can be selected based on the type of application the 3D processor is intended to be used with. In some embodiments, all SPCs 514 on may be similarly configured to accomplish similar task. In other embodiments, different SPCs 514 may be differently configured to accomplish different tasks.

In some embodiments, one or more SPCs may implement one or more of the following matrix operations/instructions: matrix-vector multiplication, matrix-matrix multiplication, vector-vector multiplication, matrix addition, matrix subtraction, vector addition, vector subtraction, matrix element-wise product, vector element-wise product, matrix scaling, and vector scaling.

Control bus 508 is generally used for all I/O, control, timing, etc. of the SPNs 502, except for the input/output of the input vectors and output vectors which can be done through 512 and broadcast bus 506. As illustrated in FIG. 5, control bus 508 can be directly accessible to means external to 3D processor die 500. For example, a top-level controller (not shown) may use control bus 508 to program weight vectors into memory banks 516 via the respective SPCs 514. In the case where 3D processor die 500 is one of many processor dies in a processing network, control bus 508 may correspond to a global control bus connecting to each of the many 3D processor dies. In contrast, each of the 3D processor dies may have its own local broadcast bus 506.

FIG. 6 shows an example of an SPC architecture that may be provided within the 3D processor die of FIG. 5. For example, illustrative SPC 600 of FIG. 6 may correspond in whole or in part to any of the SPCs 514 shown in FIG. 5. For convenience, elements of FIG. 5 are referenced in the following discussion.

Illustrative SPC 600 includes one or more computer units 602a, 602b, 602c, . . . , 602n (602 generally) each of which can include computational modules 604, accumulators 606, and register files 608. The computation models 604 may include, for example, a multiplier-adder, an algorithmic logic unit (ALU), a nonlinear function unit such as a Rectified Linear Unit (ReLU), and potentially other computational modules. Non-linear functions, such ReLU, can be used as activation functions in neural networks.

Input from the broadcast bus 506 is broadcasted to the one or more CUs 602, either directly as illustrated in FIG. 6 and/or indirectly via routing modules 512 as illustrated in FIG. 5. In the latter case, the routing modules 512 may simply forward the broadcast data to the CUS 602. All the CUS 602 can receive the same data or different data depending on whether they are computing different output vector elements or the same output vector element.

The number of CUs 602 may be selected based on the access bandwidth of the memory bank 516 (e.g., DRAM) associated with the SPC 600. For example, if the memory bank 516 can read sixty-four (64) bits of data per clock cycle and if a weight matrix element consists of eight (8) bits, then 8 CUs can be provided to perform eight (8) weight multiplications in parallel, provided that a CU can perform one weight multiplication-accumulation per clock cycle.

The CUS 602 can be designed to support many weight matrix element and vector element formats including various integer, fixed point, floating point, and potentially other formats as needed. The design can be tailored to support a single data format or multiple data formats interchangeably.

In the embodiment of FIG. 6, SPC 600 can include an output add unit 610 configured to add outputs from multiple CUs 602 before outputting the results via the routing module 512. In other embodiments, output add unit 610 may be omitted and CU 602 outputs can pass directly to the routing module 612. The optional output add unit 610 can be provided when multiple CUs are used to compute a single output vector element, for example.

Reading, writing, and refreshing of memory bank 516 is done by the SPC 600. Since all SPCs within the same die (e.g. processor die 500) work synchronously with the same broadcasted input, the reading, writing, and refreshing of different memory banks may likewise be synchronous.

Dividing up the weight matrix elements storage and output vector element computations for weight matrix times input vector can be done differently for different situations to optimize the memory usage, memory bandwidth, and computational resources. Several such situations are described next.

When one processor die is used and when the number of output vector elements are similar to but not greater than the number of SPNs, then each SPN may be used to compute one output vector. In this case, each SPN can store one row of the weight matrix. Each CU can store a subset of the row elements, and computation results from multiple CUs within the same SPN can be added to compute one output vector element.

When the number of output vector elements are similar to but not greater than the total number of CUs in the die, then each CU may be used to compute one output vector element and CU output addition is not needed.

When the number of output vector elements are much greater than the number of SPCs, then each SPC may be used to compute multiple output vector elements, with each CU multiplying an input vector element with multiple weights belonging to multiple output vector elements utilizing multiple accumulators per CU.

When one processor die is used and when the number of output vector elements are much less than the number of SPNs, then multiple SPNs may be used to compute each output vector element, each SPN storing the subset of the weight matrix row elements, and computing the corresponding sum of the partial products. In this case, the control & I/O processor 504 can be used to perform the final additions needed to compute the output vector elements, as the intermediate sums of the partial products are shifted out to the control & I/O processor 504.

When the weight matrix is large, multiple dies may be used to distribute the weight matrix storage and output vector computation. Multiple dies can be useful when the weight matrix is too large to fit within the DRAM on one die and/or when high-speed computation with low latency is required.

For example, the ID systolic array architecture shown in FIG. 4A may be used to connect multiple. In this case, if the number of output vector elements are similar to but not greater than the total number of SPNs across all the dies, then each SPN may be used to compute one output vector element. When the number of output vector elements are much greater than the total number of SPNs across all dies, but is similar to and not greater than the total number of CUs across all the dies, then each CU may be used to compute one output vector element, with each CU multiplying an input vector element with appropriate weights belonging to the output vector element. When the number of output vector elements are much greater than the total number of CUs across all dies, then each CU may be used to compute multiple output vector elements, with each CU multiplying an input vector element with multiple sets of weights belonging to the multiple output vector elements. In all these cases, the weight matrix may be distributed evenly (or as evenly as possible) across all the SPNs and SPCs to balance memory storage and computational throughput.

For very large weight matrices, it may be more efficient to use multiple dies connected in 2D systolic array architecture (FIG. 4B) to distribute the storage of weight matrix elements and output vector computation. In this case, each weight matrix row can be distributed to multiple rows of the 2D die array within the same column. The 2D matrix weight distribution can result in the same number of weights per die as 1D distribution, and the computational throughput requirement per die can also be the same. However, the data flow may possibly be faster or easier in some cases by enabling parallel input vector element distribution for each subset of weight matrix columns stored in different die rows. The sum of the partial products from different rows of the dies can be added to compute the output vector elements in this case when the weight matrix row elements belonging to one output vector element are distributed to multiple rows of the dies.

In some embodiments, a 3D processor die having a systolic or semi-systolic array architecture (such as illustrated in FIG. 5) may be programmed using one or more techniques described in U.S. Provisional Patent Application No. 63/591,513 filed on Oct. 19, 2023, and entitled “Systolic AI Processor Compiler,” which is hereby incorporated by reference herein in its entirety.

FIG. 6 is a block diagram illustrating a systolic processing core (SPC) architecture, according to some embodiments.

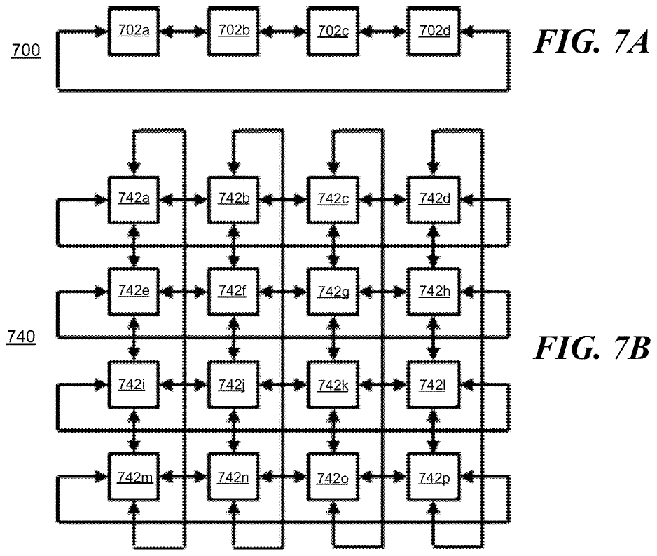

Turning to FIGS. 7A and 7B, while 1D and 2D systolic array architecture provides many design and performance advantages, embodiment of the present disclosure can achieve further improvement by utilizing the 1D and 2D toroidal systolic array architectures. For example, the general 3D processor die concept illustrated in FIG. 5 may be adapted to use a ID toroidal array. FIG. 7A shows an example of a 1D toroidal array architecture 700 having processing nodes 702a, 702b, 702c, 702d, etc. (702 generally). FIG. 7B shows an example of a 2D toroidal array architecture 740 having processing nodes 742a, 742b, . . . , 742p, etc. (742 generally). The toroidal systolic array allows for more general data flow and makes input vector element and output vector element communications easier.

As used herein, the terms “processor” and “controller” are used to describe electronic circuitry that performs a function, an operation, or a sequence of operations. The function, operation, or sequence of operations can be hard coded into the electronic circuit or soft coded by way of instructions held in a memory device. The function, operation, or sequence of operations can be performed using digital values or using analog signals. In some embodiments, the processor or controller can be embodied in an application specific integrated circuit (ASIC), which can be an analog ASIC or a digital ASIC, in a microprocessor with associated program memory, in a digital signal processor (DSP), and/or in a discrete electronic circuit, which can be analog or digital. A processor or controller can include internal processors or modules that perform portions of the function, operation, or sequence of operations. Similarly, a module can include internal processors or internal modules that perform portions of the function, operation, or sequence of operations of the module. A single processor or other unit may fulfill the functions of several means recited in the claims.

As used in the claims or elsewhere herein, the term “comprising” does not exclude other elements or steps, and the indefinite article “a” or “an” does not exclude a plurality.

As used herein, the term “predetermined,” when referring to a value or signal, is used to refer to a value or signal that is set, or fixed, in the factory at the time of manufacture, or by external means, e.g., programming, thereafter. As used herein, the term “determined,” when referring to a value or signal, is used to refer to a value or signal that is identified by a circuit during operation, after manufacture.

Various embodiments of the concepts systems and techniques are described herein with reference to the related drawings. Alternative embodiments can be devised without departing from the scope of the described concepts. It is noted that various connections and positional relationships (e.g., over, below, adjacent, etc.) are set forth between elements in the claims, detailed description, and drawings. These connections and/or positional relationships, unless specified otherwise, can be direct or indirect, and the claimed inventions are not intended to be limiting in this respect. Accordingly, a coupling/connection of entities can refer to either a direct or an indirect coupling/connection, and a positional relationship between entities can be a direct or indirect positional relationship. As an example of an indirect positional relationship, references in the present description to element or structure A coupled/connected to element or structure B include situations in which one or more intermediate elements or structures (e.g., element C) is provided between elements A and B regardless of whether the characteristics and functionalities of elements A and/or B are substantially changed by the intermediate element(s).

Furthermore, it should be appreciated that relative, directional or reference terms (e.g. such as “above,” “below,” “left,” “right,” “top,” “bottom,” “vertical,” “horizontal,” “front,” “back,” “rearward,” “forward,” etc.) and derivatives thereof are used only to promote clarity in the description of the figures. Such terms are not intended as, and should not be construed as, limiting. Such terms may simply be used to facilitate discussion of the drawings and may be used, where applicable, to promote clarity of description when dealing with relative relationships, particularly with respect to the illustrated embodiments. Such terms are not, however, intended to imply absolute relationships, positions, and/or orientations. For example, with respect to an object or structure, an “upper” or “top” surface can become a “lower” or “bottom” surface simply by turning the object over. Nevertheless, it is still the same surface and the object remains the same.

The terms “disposed over,” “overlying,” “atop,” “on top,” “positioned on” or “positioned atop” mean that a first element, such as a first structure, is present on a second element, such as a second structure, where intervening elements or structures (such as an interface structure) may or may not be present between the first element and the second element. The term “direct contact” means that a first element, such as a first structure, and a second element, such as a second structure, are connected without any intermediary elements or structures between the interface of the two elements. The term “connection” can include an indirect connection and a direct connection.

In the foregoing detailed description, various features are grouped together in one or more individual embodiments for the purpose of streamlining the disclosure. This method of disclosure is not to be interpreted as reflecting an intention that each claim requires more features than are expressly recited therein. Rather, inventive aspects may lie in less than all features of each disclosed embodiment.

References in the disclosure to “one embodiment,” “an embodiment,” “some embodiments,” or variants of such phrases indicate that the embodiment(s) described can include a particular feature, structure, or characteristic, but every embodiment can include the particular feature, structure, or characteristic. Moreover, such phrases are not necessarily referring to the same embodiment(s). Further, when a particular feature, structure, or characteristic is described in connection knowledge of one skilled in the art to affect such feature, structure, or characteristic in connection with other embodiments whether or not explicitly described.

The disclosed subject matter is not limited in its application to the details of construction and to the arrangements of the components set forth in the detailed description or illustrated in the drawings. The disclosed subject matter is capable of other embodiments and of being practiced and carried out in various ways. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

Other variations to the disclosed embodiments can be understood and effected by those skilled in the art in practicing the claimed invention, from a study of the drawings, the disclosure, and the appended claims.

The mere fact that certain measures are recited in mutually different dependent claims does not indicate that a combination of these measures cannot be used to obtain an advantage.

Any reference signs in the claims should not be construed as limiting the scope.

All publications and references cited herein are expressly incorporated herein by reference in their entirety.

1. A processor comprising:
a memory die having a plurality of memory banks;
a processor die disposed over the memory die and having a plurality of processor cores connected as a systolic array; and
a plurality of signal paths configured to couple the memory die to the processor die,
wherein each of the processor cores is disposed over at least one of the plurality of memory banks and connected thereto by at least one of the plurality of signal paths.

2. The processor of claim 1 wherein the memory banks are disposed on a horizontal surface of the memory die, the processor cores are disposed on a horizontal surface of the processor die, and the signal paths extend vertically between the memory die and the processor die.

3. The processor of claim 2 wherein each of the processor cores have a first area on the horizontal surface of the memory die, each of the memory banks have a second area on the horizontal surface of the memory die, and the first and second areas are substantially equal.

4. The processor of claim 1 wherein the plurality of processor cores comprises a plurality of application-specific integrated circuits (ASICs).

5. The processor of claim 4 wherein each of the plurality of ASICs is configured to perform the same arithmetic operations.

6. The processor of claim 4 wherein at least two different ones of the plurality of ASICs are configured to perform at least two different arithmetic operations.

7. The processor of claim 1 wherein the plurality of processor cores are configured to read and write data to the plurality of memory banks using individual memory interfaces.

8. The processor of claim 1 wherein the plurality of processor cores are connected as a one-dimensional (1D) systolic array.

9. The processor of claim 1 wherein the plurality of processor cores are connected as a two-dimensional (2D) systolic array.

10. The processor of claim 1 wherein the plurality of processor cores are connected as a toroidal systolic array.

11. A processing network comprising:
a plurality of processing nodes each having:
a memory die having a plurality of memory banks;
a processor die disposed over the memory die and having a plurality of processor cores connected as a systolic array; and
a plurality of signal paths configured to couple the memory die to the processor die.
wherein each of the processor cores is disposed over at least one of the plurality of memory banks and connected thereto by at least one of the plurality of signal paths,
wherein the plurality of processing nodes are connected as a systolic array.

12. The processing network of claim 11 wherein the plurality of processing nodes are connected as a 1D systolic array.

13. The processing network of claim 11 wherein the plurality of processing nodes are connected as a 2D systolic array.

14. A system comprising:
a control & I/O processor; and
a processor die having a plurality of processor nodes connected as a systolic array and each connected to the control & I/O processor via one or more buses,
wherein each of the plurality of processor nodes has a routing module a processor core connected to a memory bank via an individual memory interface.

15. The system of claim 14 wherein the routing modules are configured to receive data from the control & I/O processor via at least one of the one or more buses.

16. The system of claim 14 wherein the one or more buses include a broadcast bus connecting the control & I/O processor to each of the processor nodes.

17. The system of claim 16 wherein the memory banks are configured to store neural network weights, the control & I/O processor is configured to broadcast input vector elements to the plurality of processor nodes via the broadcast bus, and the plurality of processor nodes are configured to read the neural network weights from the memory banks and to multiply the input vector elements by the neural network weights to produce output vector elements.

18. The system of claim 17 wherein the processor nodes are configured to shift out the output vector elements to the control & I/O processor via the systolic array.

19. The system of claim 17 wherein the one or more buses include a control bus configured to program the neural network weights stored on the memory banks.

20. The system of claim 18 wherein the processor die is a first processor die, wherein the system further comprises:
a second processor die having a plurality of processor nodes connected as a systolic array and each connected,
wherein the control bus is arranged to connect the first and second processor dies.
